(19) United States
(12) Patent Application Publication
(10) Pub. No.: US 2021/0246542 A1
(43) Pub. Date: Aug. 12, 2021

(54) COATING APPARATUS AND METHOD FOR USE THEREOF

(71) Applicant: KVARC SERVICES INC, Mississauga (CA)

(72) Inventors: Leonid KRISHTEIN, Richmond Hill (CA); Vladimir ANISIMOV, Maple (CA); Oleg POPOV, Etobicoke (CA)

(73) Assignee: KVARC SERVICES INC, Mississauga, ON (CA)

(21) Appl. No.: 17/285,015

(22) PCT Filed: Apr. 23, 2019
(86) PCT No.: PCT/IB2019/053317

§ 371 Date: Apr. 13, 2021

Related U.S. Application Data
(60) Provisional application No. 62/769,352, filed on Nov. 19, 2018.

(51) Int. Cl. C23C 14/32; C23C 14/35; H01J 37/32; C23C 14/14; C23C 14/54

(52) U.S. Cl. CPC C23C 14/325; C23C 14/351; H01J 37/3299; H01J 37/32669; H01J 37/32935; C23C 14/14; C23C 14/543; H01J 37/32614; H01J 37/32055

(57) ABSTRACT

A cathode arc evaporator of metals and alloys for coating in a vacuum chamber, including an ignition device adapted for initiating an arc discharge, at least one anode, a water-cooled, consumable tubular cathode arranged along a longitudinal axis and rotatable thereabout, an electromagnetic system disposed within the cathode and adapted for forming an arch-like magnetic field, formed by at least one electromagnetic coil, in the vicinity of a surface of the cathode, resulting in a displaceable cathode spot, which is steerable by the magnetic field, at least one sensor responsive to the proximity of the cathode spot, and a controller which is configured to switch the polarity of the current of the at least one electromagnetic coil in response to the signals received from the at least one sensor.

### FIELD OF THE INVENTION

The present disclosure relates generally to a coating apparatus by means of evaporation of materials, and more specifically to an electric arc metal evaporator.

### BACKGROUND OF THE INVENTION

Various devices for the deposition of coatings using a Physical Vapor Deposition (PVD), are known.

Using low voltage arc for evaporation of cathode material to create a coating on a substrate in a vacuum chamber is a well-known technology.

An electric arc metal evaporator having a consumable cathode and a direct current power supply connected to cathode and anode is known (U.S. Pat. No. 3,793,179). In the above-mentioned evaporator, the surface of a substrate is coated with material evaporated by the action of a cathode spot of an electric vacuum arc which moves over a cathode surface. This type of evaporator has certain disadvantages, as the resulting uniform treatment area is relatively small and while coating elongated details, several evaporators must be disposed along the longitudinal axis of the details. Utilization of several evaporators substantially complicates the process, since each of the evaporators requires a separate power supply, controller, ignition device, vacuum seals etc.

Another evaporator is known (U.S. Pat. No. 5,037,522) having an extended cylindrical cathode, the ends of which were connected via controlled high-current switches to the negative pole of the arc power source, whereas the anode was connected to the positive pole of the power source. Sensors were located near the ends of the cathode, these sensors were configured to detect the approaching cathode spot to one end and controlling the switching to the opposite end of cathode.

The arc is displaced spirally in predefined direction over the surface of the cathode while being affected by its own electromagnetic field. A similar solution is known from (U.S. Pat. No. 5,451,308) where the location of the cathode spot was determined using balanced bridge meter and a special sensor in the form of a conductor located in parallel with respect to the axis of the cathode.

The disadvantage of both of the above-mentioned devices is the isotropic sputtering of the cathode material in all directions which makes it applicable only for coating of inner surfaces of tubular products, or placing the cathode in the center of the chamber and the products to be coated on its periphery. Additionally, the value of the intrinsic magnetic field of the arc is relatively small, thus the speed of the cathode spot displacement is accordingly low, which in turn causes significant overheating of the melted pool around the cathode spot. The overheating increases the amount of large droplets in the erosion flow, and accordingly changes the roughness of the coated surface.

Several evaporators are known, which aim to reduce the above-mentioned undesirable effect, and are known from (U.S. Pat. Nos. 5,407,551, 4,162,954, 4,673,477 and 4,724,058). These are planar evaporators, which are using a magnetic system that is disposed under the evaporated surface and forming a magnetic tunnel thereon, which is also known as a “race track” having an obround shape or an elongated ring shape.

The above-mentioned evaporators are characterized by reduced number of originating macroparticles compared to the previously-described evaporators, but the rigid magnetic fixation of the cathode spot trajectory leads to the formation of a deep groove on the cathode, and thus leads to low efficiency of cathode material utilization. In order to increase efficiency, it has been suggested to displace the magnetic tunnel relative to the working surface of the cathode. In this case, the cathode is tubular and is configured to be rotatable with respect to a fixed magnetic system, which is located on its axis, as known from (US Publication No. 2004/0069233A1).

In the above-mentioned evaporator, the magnetic field is formed by permanent magnets or electromagnets. The arc is excited between the cathode and the longitudinal anode located opposite the magnetic tunnel. One disadvantage of this evaporator is the accelerated erosion of the cathode in the curved zone of the magnetic track. The greater the ratio of the length of the cathode to its diameter, the greater the difference in the rate of erosion of the straight and curvilinear sections of the track. Accordingly, the efficiency of the cathode material utilization decreases, as more unused cathode material remains when the annular groove in the curved zone reaches its critical depth. Another disadvantage of this evaporator is the rapid build-up of deposited metal on screens, which are located in close vicinity of the magnetic track, which can result in a short circuit during the coating process.

### SUMMARY OF THE EMBODIMENTS OF INVENTION

The present invention seeks to provide an improved coating apparatus and a method of use thereof.

There is thus provided in accordance with an embodiment of the present invention a cathode arc evaporator of metals and, alloys for coating in a vacuum chamber, including an ignition device adapted for initiating an arc discharge, at least one anode, a water-cooled, consumable tubular cathode arranged along a longitudinal axis and rotatable thereabout, an electromagnetic system disposed, within the cathode and adapted for forming an arch-like magnetic field, formed by at least one electromagnetic coil, in the vicinity of a surface of the cathode, resulting in a displaceable cathode spot, which is steerable by the magnetic field, at least one sensor responsive to the proximity of the cathode spot, and a controller which is configured to switch the polarity of the current of the at least one electromagnetic coil in response to the signals received from the at least one sensor.

Preferably, the steering of the cathode spot occurs in reciprocating manner, thus increasing the efficiency of the cathode material utilization.

Further preferably, the at least one sensor is a double Langmuir probe. Alternatively, the at least one sensor is an optical sensor. Further alternatively, the at least one sensor is a magnetic sensor disposed in close vicinity of an inner wall of the cathode under the track of the cathode spot. Yet further alternatively, the at least one sensor is an acoustic sensor disposed in close vicinity of an inner wall of the cathode under the track of the cathode spot.

In accordance with an embodiment of the present invention, the at least one sensor includes a first sensor and a second sensor, which are operative alternately.

### BRIEF DESCRIPTION OF THE DRAWINGS

The present invention will be understood and appreciated more fully from the following detailed description, taken in conjunction with the drawings in which:

FIG. 1 is a simplified pictorial representation of an evaporator with its main elements, constructed and operative in accordance with an embodiment of the present invention;

FIGS. 2A-2B are a respective simplified front view representation of an embodiment of a rotatable consumable cathode and a corresponding sectional view being taken along lines A-A in FIG. 2A;

FIG. 3 is a simplified diagram illustrating the generation of signals within the evaporator of FIG. 1 as a function of time;

FIG. 4A-4C are respective simplified front view representation of another embodiment of a rotatable consumable cathode and corresponding sectional views 4B and 4C being taken along lines A-A and B-B respectively in FIG. 4A.

### DETAILED DESCRIPTION OF THE EMBODIMENTS OF INVENTION

Described below in accordance with an embodiment of the present invention is a coating apparatus, which includes a cathode arc evaporator of metals and alloys for coating in a vacuum chamber, in which the magnetic field is formed by electromagnets and is used for controlling the trajectory of the cathode spot. It is a particular feature of an embodiment of the present invention that the cathode is rotatable and the displacement of the cathode spot is enabled in a reciprocating manner only, thus substantially increasing the efficiency of the cathode material utilization, by way of limiting the trajectory of the cathode spot to the straight portions of the magnetic elongated track, as is explained in detail hereinbelow.

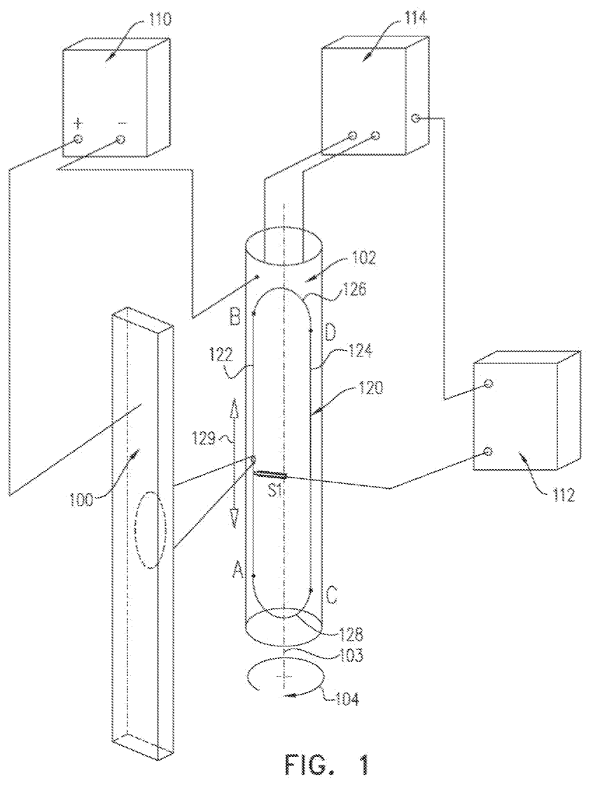

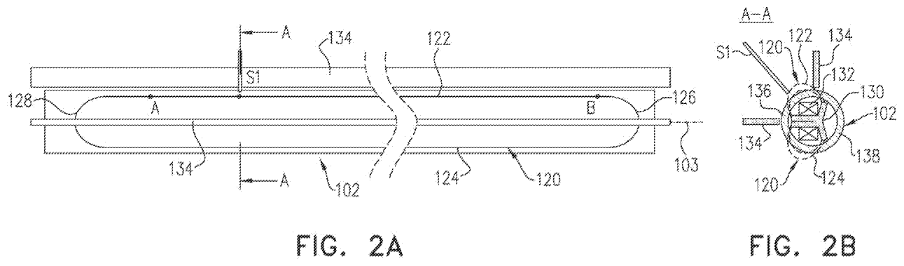

Reference is now made to FIG. 1, which is a simplified pictorial representation of an evaporator with its main elements, constructed and operative in accordance with an embodiment of the present invention. An elongated anode 100 is preferably disposed in front of a water-cooled cylindrical consumable rotatable cathode 102 arranged along a longitudinal axis 103. A stationary electromagnetic system is preferably located within the rotatable cathode 102 as described in further detail with reference to FIGS. 2 & 3 below. It is noted that the cathode 102 is configured to be rotatable about its longitudinal axis 103, as indicated by arrow 104.

An ignition device (not shown) is configured for initiating a cathodic arc using a constant current source 110, which is connected to both the anode 100 and the rotatable cathode 102.

A controller 112 is operatively coupled with a sensor “S1” and a coil control unit 114 having a power source and a switch unit which is configured for switching the polarity of the coil current of a magnetic system. The cathode spot is traveling chaotically for a short time following cathodic arc initiation. Once the cathodic arc reaches the magnet tunnel area, it becomes trapped. It is seen in FIG. 1 that the cathodic arc is steered and is forced to travel along the magnetic track 120, having a shape of a race track.

It is additionally seen in FIG. 1 that the elongated magnetic track 120 is composed of two preferably parallel straight sections 122 and 124, which extend generally in parallel to the longitudinal axis 103 and two curved sections 126, 128 connecting therebetween. Two opposite ends of the first straight section 122 are indicated by points A and B in FIG. 1. Similarly, the two opposite ends of the second straight section 124 are indicated by points C and D in FIG. 1. It is seen that the magnetic track 120 extends along the majority or along the entire longitudinal extent of the rotatable cathode 102.

It is a particular feature of an embodiment of the present invention that sensor “S1” is disposed in the vicinity of the outer surface of the rotatable cathode 102. The sensor “S1” is more particularly being disposed in the vicinity of at least one of the straight sections 122 or 124. The sensor “S1” is operatively coupled to the controller 112 and is responsive to the proximity of the cathode spot, thereby enabling tracking of the cathode spot location.

It is a further particular feature of an embodiment of the present invention that the electromagnetic system provides for formation of an arch-like magnetic field on the surface of the rotatable cathode 102, where the tangential component of the magnetic field is preferably within the range of 10-200 Gs. The magnetic field is controlled by the coil control unit 114, which is synchronized by sensor “S1”, and provides for a reciprocating longitudinal movement of the vacuum arc cathode spot along an axis extending in parallel to the longitudinal axis 103 of the rotatable cathode 102, as indicated by arrow 129.

Reference is now additionally made to FIGS. 2A and 2B, which are respective simplified front view representation of an embodiment of the rotatable consumable cathode 102 and a corresponding sectional view being taken along lines A-A in FIG. 2A.

It is noted that the rotatable cathode 102 is tubular and extends along longitudinal axis 103. A cooling water flow is arranged within the interior volume of the rotatable cathode 102.

It is particularly seen in the sectional view of the rotatable cathode 102 that a magnetic core 130 is disposed within the cathode 102 and at least one electromagnetic coil 132 is disposed adjacent thereto. It is appreciated that an electric current flows from coil control unit 114 through the electromagnetic coil 132 in order to generate the magnetic track 120. It is noted that the cathode spot is generally displaced along or in accordance with the magnetic track 120.

It is seen in FIGS. 2A and 2B that generally two shields 134 are located in the vicinity of the outer surface of the rotatable cathode 102. Each of the shields 134 generally extends longitudinally along an axis that is parallel to longitudinal axis 103. The shields 134 are circumferentially spaced from each other. One of the shields 134 is preferably positioned between the two straight portions 122 and 124 of the magnetic track 120, thus dividing the magnetic track 120 into two independent regions. A first circumferential section 136 of the rotatable cathode is located between the two shields 134 and the, remaining circumference of the rotatable cathode is indicated as a second circumferential section 138.

It is specifically seen in FIGS. 2A and 2B that the sensor “S1” is disposed in the vicinity of the first circumferential section 136 of the rotatable cathode 102, therefore the sensor “S1” is configured for tracking the cathode spot that is displaced along the first straight portion 122 of the magnetic track 120. It is noted that the second circumferential section 138 of the rotatable cathode 102 is non-active in the particular configuration that is shown in FIGS. 2A and 2B.

It is a particular feature of an embodiment of the present invention that sensor “S1” is configured for limiting the displacement of the cathode spot to the region between end points A and B of the first straight portion 122 of the magnetic track 120, as described in further detail hereinbelow.

It is a further particular feature of an embodiment of the present invention that shield 134 is disposed between the first and second straight sections 122 and 124 of the magnetic track 120, the ends of which are indicated by AB and CD respectively, such as seen in FIGS. 2A and 2B hereinabove. Using this shield 134, the magnetic system can be oriented such that the first straight section 122 is directed towards the products to be coated and the second straight section 124 is disposed in the shadow of the shield 134 and thus is rendered non-operative.

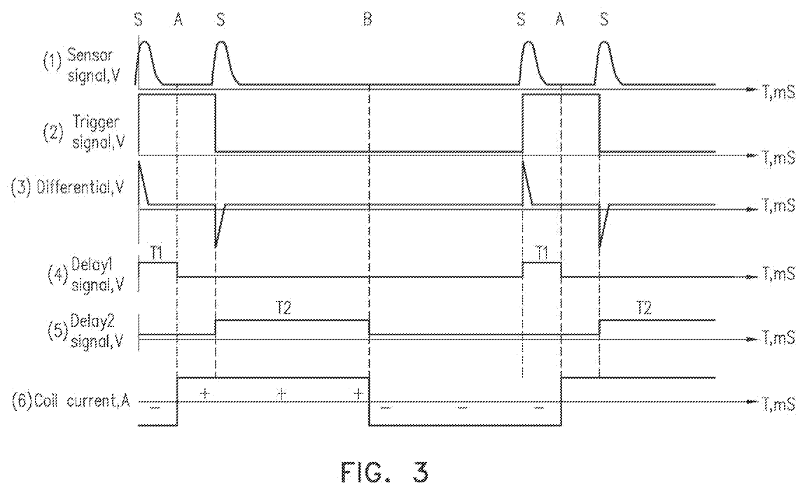

Reference is now made to FIG. 3, which is a simplified diagram illustrating the generation of signals within the evaporator of FIG. 1 as a function of time.

It is seen in FIG. 3 that the diagram is composed of six different sub-diagrams, each of which shows a signal characteristic at different spatial points during different points in time. The spatial points are indicated at the top of the diagram as follows: “S” indicating the sensor; “A” indicating one of the end points of the first straight section 122 and “B” indicating the other end point of the first straight section 122. Signal changes at each of these spatial points are illustrated as correlated to each other as a function of time. The signal processing is implemented by the coil control unit 114 having the compatible switches and capable of changing the current of the electromagnetic coil, and which is further controlled by controller 112. The controller 112 allows adjusting the sensitivity level and regulates operable time delays T1 and T2, which are described hereinbelow.

It is appreciated that the circuit is pre-defined such that current having the same polarity is used at each instance of arc ignition. If for example, the arc is initiated adjacent end point “B” and the cathode spot travels in the direction of point “A”: Once the cathode spot approaches the location of the sensor “S1”, the sensor “S1” produces the first pulse, as is shown on diagram (1) in FIG. 3. This pulse initiates a trigger pulse, as shown on diagram (2) in FIG. 3. The trigger output signal is differentiated, as seen on diagram (3) in FIG. 3 and once there is a positive signal, the first timer is started, processing the delay T1, as shown on diagram (4) in FIG. 3. Once time T1 has elapsed, the cathode spot reaches point “A” and the timer returns to its initial state, producing a pulse which is configured to switch the polarity of the current in the electromagnetic coil 132, as seen on diagram (6) in FIG. 3. Cathode spot changes its direction and moves to point B. Once the cathode spot reaches the “S” area again, sensor “S1” produces a second pulse, which switches the trigger off, as shown on diagram (2) in FIG. 3. forming a negative differential pulse on diagram (3) in FIG. 3. This negative pulse starts the second timer, processing the delay T2, as shown on diagram (5) in FIG. 3. Once time T2 has elapsed, the cathode spot reaches point “B” and the timer returns to its initial state, producing a pulse configured to switch the polarity of the current in the electromagnetic coil 132, as seen on diagram (6) in FIG. 3, and thus reverses the cathode spot back towards point “A”.

It is noted that timers which provide for time delay T1 and T2 are utilized for compensating the non-definitive position of the sensor “S1” with respect to end points AB.

The above-mentioned process is repeated recursively, thereby providing for reciprocating displacement of the cathode spot, which ensures uniform utilization of the rotatable cathode material.

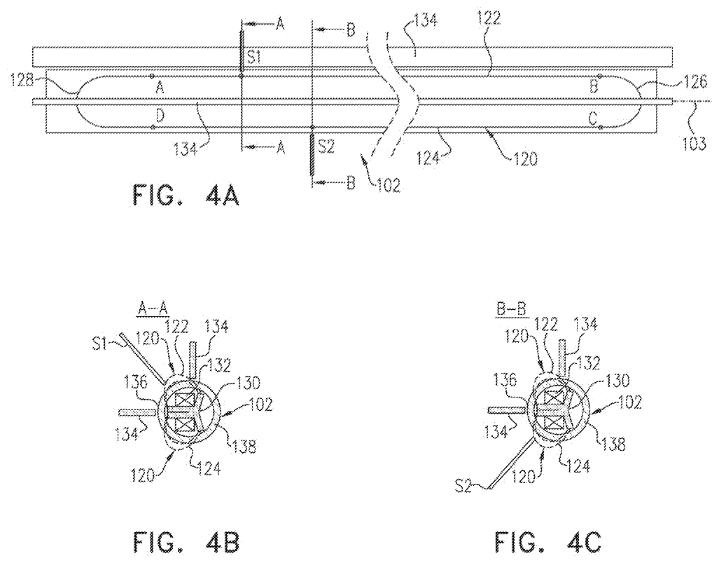

Reference is now additionally made to FIGS. 4A-4C, which are respective simplified front view representation of another embodiment of the rotatable consumable cathode 102 and a corresponding sectional views being taken along lines A-A and B-B respectively in FIG. 4A.

It is noted that the rotatable cathode 102 is tubular and extends along longitudinal axis 103. A cooling water flow is arranged within the interior volume of the rotatable cathode 102.

It is particularly seen in the sectional view of the rotatable cathode 102 that a magnetic core 130 is disposed within the cathode 102 and at least one electromagnetic coil 132 is disposed adjacent thereto. It is appreciated that an electric current flows from coil control unit 114 through the electromagnetic coil 132 in order to generate the magnetic track 120. It is noted that the cathode spot is generally displaced along or in accordance with the magnetic track 120.

It is seen in FIGS. 4A-4C that generally two shields 134 are located in the vicinity of the outer surface of the rotatable cathode 102. Each of the shields 134 generally extends longitudinally along an axis that is parallel to longitudinal axis 103. The shields 134 are circumferentially spaced from each other. One of the shields 134 is preferably positioned between the two straight portions 122 and 124 of the magnetic track 120, thus dividing the magnetic track 120 into two independent regions. A first circumferential section 136 of the rotatable cathode is located between the two shields 134 and the remaining circumference of the rotatable cathode is indicated as a second circumferential section 138.

It is specifically seen in FIGS. 4A-4C that sensor “S1” is disposed in the vicinity of the first circumferential section 136 of the rotatable cathode 102, therefore the sensor “S1” is configured for tracking the cathode spot that is displaced along the first straight portion 122 of the magnetic track 120.

It is further seen in FIGS. 4A-4C that sensor “S2” is disposed in the vicinity of the second circumferential section 138 of the rotatable cathode 102, therefore the sensor “S2” is configured for tracking the cathode spot that is displaced along the second straight portion 124 of the magnetic track 120.

It is a particular feature of an embodiment of the present invention that the first sensor “S1” and the second sensor “S2” are operative alternately, therefore, if sensor “S1” tracks the cathode spot displacement along the first straight portion 122, then the first circumferential section 136 of the cathode 102 is active. If sensor “S2” tracks the cathode spot displacement along the second straight portion 124, then the second circumferential section 138 of the cathode 102 is active.

It is a particular feature of an embodiment of the present invention that sensor “S1” is configured for limiting the displacement of the cathode spot to the region between end points A and B of the first straight portion 122 of the magnetic track 120, as described in further detail hereinbelow.

It is a further particular feature of an embodiment of the present invention that sensor “S2” is similarly configured for limiting the displacement of the cathode spot to the region between end points C and D of the second straight portion 124 of the magnetic track 120, when sensor “S1” is not actuated.

It is noted that sensor “S1” can be positioned at any point along the longitudinal extent of the rotatable cathode 102. Similarly, sensor “S2” can be positioned at any point along the longitudinal extent of the rotatable cathode. It is seen particularly in FIGS. 4A-4C that sensor “S1” and sensor “S2” can be located at a different point along the longitudinal extent of the rotatable cathode 102.

It is a particular feature of an embodiment of the present invention that, if the circuit is equipped with a second sensor “S2”, as shown and explained with reference to FIGS. 4A-4C, which is positioned in the vicinity of the second straight section 124 having end points CD, then the displacement of the cathode spot along this section can be similarly scanned and manipulated such as to allow only reciprocating displacement of the cathode spot along an axis that is parallel to the longitudinal axis 103 of the rotatable cathode 102, as described in detail with reference to FIG. 3 hereinabove. It is noted that the sensors “S1” and “S2” are operable alternately.

It is noted that in some cases it is necessary to produce bombardment of gaseous ions in order to remove residual fats, oxides, and other contaminants remaining on the surface of the products to be coated, before the deposition of coating. For this purpose, an arc discharge having a shield is used, which does not allow metal ions and microdroplets to settle onto the product. The arc acts as an effective emitter of electrons that ionize the atoms of an inert gas, the gas being specifically fed into the vacuum chamber during this bombardment process. Products to be coated are under a negative bias potential and positively charged gaseous ions carry out the ion bombardment.

In accordance with the embodiment of the invention shown in FIGS. 4A-4C, if sensor “S2” which is disposed on the second straight section 124 is connected to the controller 112, then the ion-gas cleaning can be implemented. Alternately, if sensor “S1” which is disposed on the first straight section 122 is connected to the controller 112, then deposition of the cathode metal can be implemented. It is noted that there is an electric switching between the two above-mentioned functions of the evaporator. It is noted that the above-mentioned functions of the evaporator can be performed interchangeably by either sensor “S1” or sensor “S2”.

It is a particular feature of an embodiment of the present invention that using a sensor, such as “S1” or “S2” as part of the evaporator having a rotatable cathode 102 leads to separation of the magnetic track 120 into two independent regions and the displacement of the cathode spot is only allowed along one of the straight sections 122 or 124, along longitudinal axis, which is parallel to the longitudinal axis 103 of the cathode 102. It is noted that the cathode spot is stopped before reaching the curved sections 126 or 128 of the magnetic track 120 responsive to signals received by the sensors “S1” or “S2” respectively, and causing the cathode spot to be displaced longitudinally in an opposite direction upon reaching either point A or B on the first straight section 122 or point C or D on the second straight section 124 by means of changing the polarity of the current of the electromagnetic coil 132. Thus, the cathode spot is being displaceable from point A to B and back from point B to A, responsive to the signals received by sensor “S1”, when sensor “S1” is actuated. Similarly, the cathode spot is being displaceable from point C to D and back from point D to C, responsive to the signals received by sensor “S2”, when sensor “S2” is actuated. This controlled displacement of the cathode spot provides for a uniform wear of the cathode material over the entire length thereof. It is noted that in accordance with an embodiment of the present invention, the efficiency of the cathode material utilization is substantially increased, preferably reaching more than 90% of material utilization.

The coating device in accordance with an embodiment of the present invention employs one of the sensors “S1” or “S2”, which can be configured as a double Langmuir probe. the operation of which is disclosed in detail in O. V. Kozlov “Electrical probe in plasma.” Moscow: “Atomizdat”, 1969 (in Russian), which is incorporated by reference herein. The double Langmuir probe has two conducting segments spaced from each other by approximately 5 mm and connected in series with a DC source (not shown). The circuit current is proportional to the plasma concentration surrounding the probe. The closer the cathode spot to the probe, the greater the circuit current is. It is noted that the magnitude of this current is limited by the internal resistance of the double plasma layer surrounding the probe, the probe is given under a floating potential and therefore does not act as a part of an anode, even if positioned at a very close proximity to the cathode spot. The probe is configured to be positioned in the vicinity of the outer surface of the rotatable cathode 102. Various double Langmuir probes are commercially available, such as for example from CCR Process Products, Canada, “Langmuir Double Probe—Impedans”.

It is a particular feature of an alternative embodiment of the present invention that at least one of the sensors “S1” or “S2” can be configured as an optical sensor for tracking the location, of the cathode spot. In this case, a photodiode having an optical fiber is being used as a photodetector. The light emission of a cathode spot substantially exceeds the intensity of the light emission from the anode column, which guarantees the reliable localization of the cathode spot. The optical sensor is configured to be positioned in the vacuum chamber and aimed at a specific point of the outer surface of the rotatable cathode 102. Alternatively, the optical sensor can be positioned outside of the vacuum chamber. Various optical sensors are commercially available, such as for example from Keynce Canada Inc, “Fiber Unit”.

It is a particular feature of a further alternative embodiment of the present invention that at least one of the sensors “S1” or “S2” can be configured as a magnetic sensor, for tracking the location of the cathode spot. In this case, the magnetic sensor is located inside the rotatable cathode 102, preferably underneath the working section of the magnetic track 120. A highly sensitive magnetic element is located within a special magnetic screen, which is adapted to eliminate the influence of the magnetic system coils 132. The frequency of the cathode arc signal is generally higher than the switching frequency of the coils 132, which enables an effective identification of the cathode spot signal while disregarding the background noise. The magnetic sensor is configured to be positioned in the vicinity of the inner surface of the rotatable cathode 102 under the cathode spot track. Various magnetic sensors are commercially available, such as for example from Electro Magnetic Components Inc, Calif., USA, Cat. No. 998-023-5654.

It is a particular feature of a yet further alternative embodiment of the present invention that at least one of the sensors “S1” or “S2” can be configured as an acoustic sensor for tracking the location of the cathode spot. In this case, the acoustic sensor is located inside the rotatable cathode 102, preferably underneath the working section of the magnetic track 120. The vibrations caused by the thermal cycle of the cathode spot propagate into the cathode material, further they are passed into the incompressible fluid medium and act on the elastic membrane of the piezoelectric transducer, which is in turn utilized for tracking the location of the cathode spot. The acoustic sensor is configured to be positioned in the vicinity of the inner surface of the rotatable cathode 102 under the cathode spot track. Various acoustic sensors are commercially available, such as for example from Digi-Key Electronics, Canada, Cat. No. MSP1007-ND.

It will be appreciated by persons skilled in the art that the present invention is not limited by what has been particularly shown and described hereinabove. Rather the scope of the present invention includes both combinations and sub-combinations of various features described hereinabove as well as variations and modifications thereof which are not in the prior art.

1. A cathode arc evaporator of metals and alloys for coating in a vacuum chamber, comprising:
an ignition device adapted for initiating an arc discharge,
at least one anode,
a water-cooled, consumable tubular cathode arranged along a longitudinal axis and rotatable thereabout,
an electromagnetic system disposed within said cathode and adapted for forming an arch-like magnetic field, formed by at least one electromagnetic coil, in the vicinity of a surface of said cathode, resulting in a displaceable cathode spot, which is steerable by said magnetic field,
at least one sensor located within said consumable tubular cathode and responsive to the proximity of said cathode spot,
and a controller which is configured to switch the polarity of the current of said at least one electromagnetic coil in response to the signals received from the at least one sensor.

2. The cathode arc evaporator of metals and alloys for coating in vacuum according to claim 1, and wherein the steering of the cathode spot occurs in reciprocating manner, thus increasing the efficiency of the cathode material utilization.

3.-4. (canceled)

5. The cathode arc evaporator of metals and alloys for coating in vacuum, according to claim 1 and wherein said at least one sensor is a magnetic sensor disposed in close vicinity of an inner wall of said cathode under the track of said cathode spot.

6. The cathode arc evaporator of metals and alloys for coating in vacuum, according to claim 1 and wherein said at least one sensor is an acoustic sensor disposed in close vicinity of an inner wall of said cathode under the track of said cathode spot.

7. The cathode arc evaporator of metals and alloys for coating in vacuum, according to claim 1 and wherein said at least one sensor includes a first sensor and a second sensor, which are operative alternately.

8. The cathode arc evaporator of metals and alloys for coating in vacuum, according to claim 7 and wherein said at least one sensor is a double Langmuir probe.

9. The cathode arc evaporator of metals and alloys for coating in vacuum, according to claim 1 and wherein said at least one sensor is an electromagnetic sensor disposed in close vicinity of an inner wall of said cathode under the track of said cathode spot.
